(19) United States
(12) Patent Application Publication
(10) Pub. No.: US 2021/0193855 A1
(43) Pub. Date: Jun. 24, 2021

(54) Photovoltaically Active Laminate

(71) Applicant: Audi AG, Ingolstadt (DE)

(72) Inventors: Wojciech BRYMERSKI, Kornwestheim (DE); Annegret MATTHAI, Rohrbach (DE)

(73) Assignee: Audi AG, Ingolstadt (DE)

(21) Appl. No.: 17/055,897

(22) PCT Filed: Jun. 5, 2019
(86) PCT No.: PCT/EP2019/064670

§ 371 Date: Nov. 16, 2020

(30) Foreign Application Priority Data
Jun. 8, 2018 (DE) 10 2018 209 112.9

(51) Int. Cl. H01L 31/048; B32B 7/025; B60R 1/00; B60L 8/00; H02S 10/40; B32B 27/40; B32B 27/34; B32B 27/36; B32B 27/30; B32B 27/18; B32B 27/12; C09J 7/29; C09J 7/40

(52) U.S. Cl. CPC H01L 31/0481; B32B 2262/101; B60R 1/001; B60L 8/003; H02S 10/40; B32B 27/40; B32B 27/34; B32B 27/365; B32B 27/302; B32B 27/18; B32B 27/306; B32B 27/12; C09J 7/29; C09J 7/40; B32B 2457/12; B32B 2307/412; B32B 2605/08; B32B 2305/08; B32B 2262/106; B32B 7/025

(57) ABSTRACT

The present disclosure relates to a photovoltaically active laminate that includes a cover film, a photovoltaic active solar cell film, and a fiber composite support layer. The cover film defines a top surface of the laminate and is transparent to incident light radiation. The photovoltaic active solar cell film includes a support film and a coating of a photovoltaically active material applied to the support film. The cover film has a thickness in a range up to 1 mm. The solar cell film has a thickness in a range between 0.06 mm and 2 mm. The support layer has a thickness in a range between 0.8 mm and 3 mm.

### TECHNICAL FIELD

The invention relates to a photovoltaically active laminate.

### BACKGROUND

In the case of vehicles that are powered exclusively electrically or in the case of hybrid vehicles that are at least partially electrically powered, one or more energy storages are provided, which are to be charged from time to time. For this purpose, in addition to the usual charging technology using a charging cable or inductive charging, it is known to provide solar cells on the components forming the outer shell of the vehicle, such as a panoramic roof or a panoramic sliding roof. These solar cells are usually built into components made of glass, such as the panoramic roof or panoramic sliding roof mentioned, the structure of such a glass roof module consisting of an upper and a lower glass layer, between which the solar cells are inserted. In this sandwich structure, the solar cell level is located quasi in the middle of the sandwich structure, with one or more support films being introduced between the solar cell level and the upper and lower glass levels. The entire structure is rigid, since the panoramic roof or panoramic sliding roof has the function of a central, stable roof module.

### SUMMARY OF INVENTION

An embodiment of the invention is based on the problem of specifying a photovoltaically active component which is more flexible in its handling and possible uses.

To solve this problem, a photovoltaically active laminate is provided according to an embodiment of the invention, comprising at least a cover film which forms the top surface of the laminate and which is transparent to incident light radiation, a photovoltaically active solar cell film, and a fiber composite support layer.

According to an embodiment of the invention, a photovoltaically active laminate is proposed which is extremely thin and is flexible overall. This means that, due to the flexibility thereof, it can be attached to the external shell of the motor vehicle, even if it is not flat, but rather is curved or has correspondingly narrower radii, etc., as in the case of a front flap or bonnet, a tailgate, doors, etc. This flexible laminate can therefore be attached to the vehicle at different positions, and this installation can also take place later on. Of course, the photovoltaically active laminate can also be installed on other objects, which means that the use thereof is not restricted to the motor vehicle sector.

The laminate according to an embodiment of the invention comprises a cover film which is transparent to the incident light radiation and which forms the top surface of the laminate. This cover film is preferably made of PU (polyurethane), SAN (styrene-acrylonitrile), PC (polycarbonate), or PA (polyamide), although other plastics material films can also be used which have the desired mechanical and, in particular, transparency properties. This is because the cover film must be transparent to the incident light radiation that is to be converted by the solar cell film located within the laminate sandwich, i.e., it should have as little absorption as possible. As described, this cover film is sufficiently stable and can serve as a paint substitute if the laminate according to an embodiment of the invention is applied directly to the corresponding body component before it is painted. For this purpose, the cover film can also be colored in order to take appropriate color requirements into account.

The laminate further comprises a photovoltaically active solar cell film, i.e., an extremely thin film with correspondingly formed solar cells. Such flexible solar cell films comprise an extremely thin support film, for example made of polyimide, to which a photovoltaically active layer, for example made of cadmium telluride (CdTe), is applied, which is optionally enclosed on the back by another extremely thin support film, for example made of polyimide. The entire film or layer structure is extremely thin and therefore extremely flexible.

Furthermore, the laminate according to an embodiment of the invention comprises a thin, flexible support layer made of a fiber composite material, which gives the laminate sufficient stability. This support layer can for example be made of glass-fiber-reinforced or carbon-fiber-reinforced plastics material, wherein such a support layer can also be produced extremely thin, so that overall an extremely thin laminate structure results, which allows for the advantageous flexibility.

The laminate according to an embodiment of the invention is therefore also extremely light, compared to previously known solar components comprising one or more glass levels, which results in a lower overall weight, for example when used in the automotive sector, combined with the possibility of allowing a significantly greater solar surface due to the possibility of attachment to differently shaped vehicle exterior surfaces.

The cover film itself should have a thickness of up to 1 mm. As stated, it can be a transparent film, but it can also be colored, but there must always be a sufficiently high level of light or radiation transparency so that the light hits the solar cell film with as little attenuation as possible and the latter can convert light energy into electrical energy with a sufficiently high degree of efficiency.

The solar cell film itself should have a thickness of at least 0.06 mm, in particular between 0.06-2 mm. The thickness is preferably in the range from approx. 0.3-0.5 mm.

The support layer should have a thickness of at least 0.8 mm, in particular between 0.8-3 mm. Of course, the thinner the individual films/layers, the more flexible the laminate structure.

According to a first alternative embodiment of the invention, the laminate according to an embodiment of the invention can only consist of the cover film, the solar cell film, and the support layer. In this case, the cover film is applied directly to the solar cell film and the solar cell film in turn is applied directly to the support layer.

Alternatively, there is the possibility of providing at least one intermediate film, which is arranged between the cover film and the support layer. The solar cell film can be enclosed on one side using this intermediate film; it serves as a protective film to space apart the solar cell film as little as possible from either the cover film or the support layer, the intermediate film also having the smallest possible thickness; it should be at least 0.1 mm, and preferably between 0.1-1 mm thick.

The intermediate film is preferably arranged between the solar cell film and the support layer, so it serves to shield the solar cell film from the support layer made of GRP (glass fiber reinforced plastics material) or CFRP (carbon fiber reinforced plastics material). In addition, an intermediate film can also be arranged between the cover film and the solar cell film, i.e., the solar cell film is enclosed on both sides by a support film and shielded from the respective adjacent cover film or support layer.

The intermediate film itself can be made of the same material as the cover film, i.e., it can also be made of PU, SAN, PC or PA, for example. However, an intermediate film made of PVB (polyvinyl butyral) is preferably used.

In order to allow the installation of the laminate according to an embodiment of the invention on a substrate to be as simple as possible, it is conceivable to provide the laminate, in an already prefabricated manner, with an adhesive located on the support layer, by means of which adhesive the laminate can be glued to a surface, the adhesive being covered with a removable protective film, for example a silicone paper. This means that the laminate is already equipped with an appropriate adhesive at the factory.

A direct application of adhesive can be provided as the adhesive, for example, which is sprayed onto the support layer or is applied by means of a calender or the like. Alternatively, an adhesive film, in particular a double-sided adhesive film, can also be used as the adhesive, which is also applied, for example, by means of a calender.

In addition to the photovoltaically active laminate according to an embodiment of the invention, an embodiment of the invention also relates to a motor vehicle in which at least one outer surface is covered with a photovoltaically active laminate of the type described.

The laminate can be glued to the outer surface by means of an adhesive, in particular an adhesive film. If the laminate itself is not already equipped with an adhesive, this adhesive can be applied when laying the laminate.

### BRIEF DESCRIPTION OF THE FIGURES

Further advantages and details of the present invention will become apparent from the embodiments described below and with reference to the drawings, in which:

FIG. 1 shows a schematic diagram, in section, through a laminate according to a first embodiment of the invention,

FIG. 2 shows a schematic diagram, in section, through a laminate according to a second embodiment of the invention,

FIG. 3 shows a schematic diagram, in section, through a laminate according to a third embodiment of the invention, and

FIG. 4 shows a schematic diagram of a motor vehicle according to a fourth embodiment of the invention.

### DETAILED DESCRIPTION OF THE FIGURE

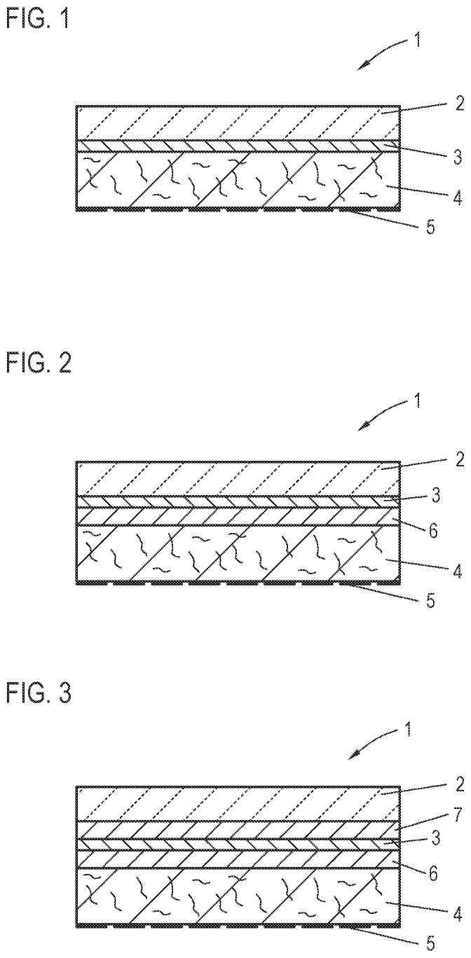

FIG. 1 shows a laminate 1 according to an embodiment of the invention in the form of a schematic diagram. According to the embodiment, laminate 1 can include a cover film 2, for example made of PU, PC, SAN, or PA. The cover film 2 is transparent, but can also be colored. In any case, it is transparent to incident light radiation, so that light can pass through the cover film 2 with as little attenuation as possible. Instead of the types of film mentioned, another amorphous plastics material can also be used, as long as it is sufficiently stable and sufficiently transparent, but is nevertheless flexible.

According to the embodiment, cover film 2 is applied to a solar cell film 3 which has a thickness of at least 0.06 mm, preferably a thickness of approximately 0.3-0.5 mm. It can be a polyimide film to which a photovoltaically active material, for example cadmium telluride, is applied in an extremely thin coating. However, other photoactive materials or support films are also conceivable. In any case, this solar cell film is also extremely thin and flexible.

According to the embodiment, solar cell film 3, in turn, is applied to a support layer 4 made of glass fiber or carbon fiber reinforced composite material, this support layer also being extremely thin and flexible. It has a thickness of approx. 0.8-3 mm. Overall, this creates an extremely thin laminate structure that is extremely light and flexible, so that it can be attached to different geometric objects, for example to the outer shell of a motor vehicle body, despite their curvatures, etc.

For easier installation, it is conceivable to provide the laminate 1 with an adhesive 5 that is applied to the support layer 4, although this is optional and therefore does not necessarily have to be done at the factory, which is why this adhesive 5 in FIG. 1 is only shown in dashed lines. The adhesive 5 can, for example, be a direct application of adhesive, which is covered with a removable protective film, for example silicone paper, but it can also be a double-sided adhesive film, which is also covered with such a protective film. The laminate according to an embodiment of the invention can easily be glued to the desired surface via this adhesive 5.

FIG. 2 shows a laminate 1 according to another embodiment of the invention, again comprising a cover film 2 of the type described above. A solar cell film of the prescribed type, on which the cover film 2 is applied, is also provided.

In contrast to the configuration according to FIG. 1, the solar cell film is applied to an intermediate film 6, which is also extremely thin; it preferably has a thickness of 0.1-1 mm. It is preferably a PVB film, but this intermediate film can also be the same plastics material as the cover film 2. This intermediate film serves to shield the solar cell film 3 from the support layer 4, i.e., the intermediate film 6 is applied to the support layer 4, which has already been described above for FIG. 1.

In this case, too, an adhesive 5 can optionally be applied to the support layer 4.

FIG. 3 also shows a laminate 1 according to an embodiment of the invention, which likewise has a cover film 2 of the type described above. In contrast to the configuration according to FIG. 2, however, this is applied to a second intermediate film 7, which can preferably be a PVB film with a thickness of 0.1-1 mm, but it can also include consist of the same plastics material as the cover film 2. This second intermediate film 7 is applied to the solar cell film 3 of the type described above, so it serves as a protective film for the same toward the cover film 2.

The solar cell film 3 is in turn, similar to FIG. 2, applied to a first intermediate film 6, preferably again a PVB film, or designed corresponding to the second intermediate film 7, which in turn is applied to the support layer 4. In this case, too, the overall result is an extremely thin laminate structure which is still sufficiently flexible, since all the films or layers used are extremely thin and, in turn, flexible.

The application of an adhesive 5 is optionally also shown in this case in dashed lines.

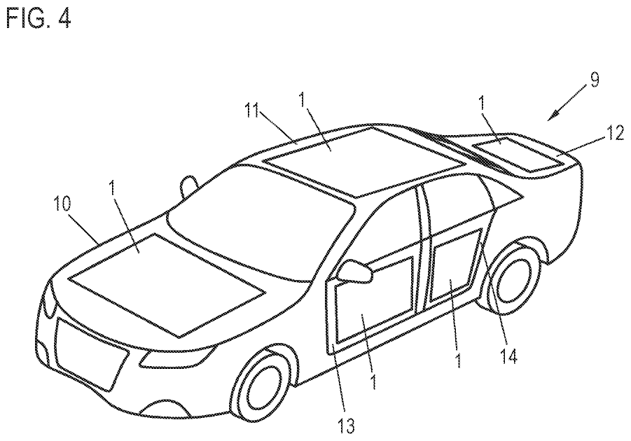

FIG. 4 shows a motor vehicle 9 according to an embodiment of the invention, which is either a purely electric vehicle, which is therefore only operated electrically, or a hybrid vehicle. As shown, the outer surface of the motor vehicle 9 is covered over a large area in a plurality of places with a laminate 1 according to embodiments of the invention. For example, the laminate 1 can be glued onto the front hood or bonnet 10, it can also be glued onto the roof 11 or the trunk lid or tailgate 12 over a large area. The fastening at these positions is advantageous as there is a very good incidence of light during the day.

Additionally or alternatively, the arrangement of the laminate can also take place on the doors 13, 14.

The laminate or laminates 1, which can also be referred to as solar cell laminates or flexible solar cell modules, are preferably coupled directly to the high-voltage circuit via which the motor vehicle 9 can be electrically operated or driven, i.e., the “solar power” generated by them can be fed directly into this high-voltage circuit so that the range of electrically powered vehicles can be increased. It is also conceivable to store this “solar power” in a corresponding energy storage device or to buffer it and use it if necessary.

1.-14. (canceled)

15. A photovoltaic active laminate for directly attaching to a non-planar surface, comprising:
a cover film defining a top surface of the laminate, the cover film being transparent to incident light radiation;
a photovoltaic active solar cell film comprising a support film and a coating of a photovoltaic active material applied to the support film;
a fiber composite support layer; and
an adhesive disposed on the support layer and covered by a removable protective film, the adhesive configured to adhere the laminate to the non-planar surface,
wherein the cover film has a thickness in a range up to 1 mm, the solar cell film has a thickness in a range between 0.06 mm and 2 mm, and the support layer has a thickness in a range between 0.8 mm and 3 mm.

16. The photovoltaic active laminate according to claim 15, wherein the cover film comprises polyurethane, styrene-acrylonitrile, polycarbonate, or polyamide.

17. The photovoltaic active laminate according to claim 15, wherein the support layer comprises glass-fiber-reinforced or carbon-fiber-reinforced plastics material.

18. The photovoltaic active laminate according to claim 15, wherein the cover film is disposed directly on the solar cell film, and the solar cell film is disposed directly on the support layer.

19. The photovoltaic active laminate according to claim 15, further comprising:
one or more intermediate films disposed between the cover film and the support layer.

20. The photovoltaic active laminate according to claim 19, wherein the one or more intermediate films are disposed between the solar cell film and the support layer.

21. The photovoltaic active laminate according to claim 19, wherein the one or more intermediate films include a first intermediate film disposed between the cover film and the solar cell film and a second intermediate film disposed between the solar cell film and the support layer.

22. The photovoltaic active laminate according to claim 19, wherein the one or more intermediate films are comprised of a same material as the cover film.

23. The photovoltaic active laminate according to claim 19, wherein the one or more intermediate films comprise polyvinyl butyral.

24. The photovoltaic active laminate according to claim 19, wherein the one or more intermediate films each have a thickness in a range between 0.1 mm and 1 mm.

25. The photovoltaic active laminate according to claim 15, wherein the adhesive comprises an adhesive film.

26. A motor vehicle comprising:
one or more outer surfaces;
a photovoltaic active laminate disposed on the one or more outer surfaces, wherein the photovoltaic active laminate comprises:
a cover film defining a top surface of the laminate, the cover film being transparent to incident light radiation,
a photovoltaic active solar cell film comprising a support film and a coating of a photovoltaic active material applied to the support film, and
a fiber composite support layer,
wherein the cover film has a thickness in a range up to 1 mm, the solar cell film has a thickness in a range between 0.06 mm and 2 mm, and the support layer has a thickness in a range between 0.8 mm and 3 mm.

27. The motor vehicle according to claim 26, wherein the laminate is adhered to the one or more outer surfaces by an adhesive film.
